(19) United States
(12) Patent Application Publication
(10) Pub. No.: US 2025/0384924 A1
(43) Pub. Date: Dec. 18, 2025

(54) SEMICONDUCTOR DEVICE

(71) Applicant: Renesas Electronics Corporation, Tokyo (JP)

(72) Inventors: Shunya NAGATA, Tokyo (JP); Kouji SATOU, Tokyo (JP); Daisuke NAKAMURA, Tokyo (JP)

(21) Appl. No.: 19/068,089

(22) Filed: Mar. 3, 2025

(30) Foreign Application Priority Data
Jun. 18, 2024 (JP) 2024-098282

(51) Int. Cl. G11C 11/419; G11C 11/412; H10B 10/00

(52) U.S. Cl. CPC G11C 11/419; G11C 11/412; H10B 10/12

(57) ABSTRACT

A read assist circuit is configured so as to be capable of switching validation/invalidation, and lowers a word line voltage applied to a word line in order to secure a static noise margin of a memory cell when being valid. An SNM detection circuit has a replica memory cell configured so as to make data retention ability lower than that of memory cell. The SNM detection circuit detects the static noise margin of the memory cell in a pseudo manner by using the replica memory and cell, switches the validation/invalidation of the read assist circuit depending on a detection result.

### CROSS-REFERENCE TO RELATED APPLICATIONS

The present application claims priority from Japanese Patent Application No. 2024-98282 filed on Jun. 18, 2024, the content of which is hereby incorporated by reference to this application.

### BACKGROUND

The present invention relates to a semiconductor device, for example, a semiconductor device including a Static Random Access Memory (SRAM).

There is disclosed techniques listed below.

### [Non-Patent Document 1] Inhak Lee et al, “A Voltage and Temperature Tracking SRAM Assist Supporting 740 mV Dual-Rail Offset for Low-Power and High-Performance Applications in 7 nm EUV FinFET Technology”, ISSCC 2019

### [Non-Patent Document 2] Belal Iqbal et al, “Actively Compensated Read Assist Technique for 0.6 V Operation of 16 Mb High Density SRAM in 65 nm LSTP”, INDICON 2020

Non-Patent Document 1 discloses a configuration of applying a TATA circuit to an SRAM assist circuit. The TATA circuit determines a step-down level of a word line voltage by using a voltage between a gate and a source of a diode-connected MOS transistor. Consequently, the TATA circuit generates the lower word line voltage as temperature rises.

Non-Patent Document 2 discloses a configuration of having a PVT monitor sensor to generate a trigger for an SRAM read assist circuit. The PVT monitor sensor compares magnitude between an output voltage from a process monitor circuit (PMC) and an output voltage from a bandgap reference (BGR) circuit, and controls on/off of the trigger for the read assist circuit based on its results.

### SUMMARY

For example, in the SRAM, assist control for securing an operating margin of a memory cell becomes unavoidable by an increase in manufacturing variations along with miniaturization. Specifically, since a static noise margin of the memory cell lacks, particularly, at high temperature, incorporation of the read assist circuit for improving this lack becomes essential. The typical read assist circuit is a circuit slightly lowering the word line voltage at a time of a read access of the SRAM. However, if the word line voltage is lowered, a memory cell current at the time of the read access lowers as side effect, so that an increase of access time can occur.

Here, for example, the configurations disclosed in Non-Patent Documents 1 and 2 have been known about the read In the configuration disclosed in Non-assist circuit. Patent Document 1, the read assist circuit changes an assist amount depending on the temperature. However, the read assist circuit always operates with changing the assist amount, so that the increase of the assess time can always occur, too.

Meanwhile, the configuration disclosed in Non-Patent Document 2, on/off, that is, validation/invalidation of the read assist circuit can be switched by using the PVT monitor sensor. However, the PTV monitor sensor requires a comparatively large circuit area. In addition, the PVT monitor sensor may take some time for temperature detection. In this way, in the configurations disclosed in Non-Patent Documents 1 and 2, the increase of the access time with the read assist may not be suppressed efficiently.

An embodiment(s) explained later has been made in view of the above, and the other problems and novel features will be apparent from the present specification and the accompanying drawings.

A semiconductor device according to one embodiment includes an SRAM and a detection circuit detecting a static noise margin of the SRAM. The SRAM has a memory array and a read assist circuit. The memory array has a word line, a bit line pair, and a memory cell connected to the word line and the bit line pair. The read assist circuit is configured so as to be capable of switching validation/invalidation, and lowers a word line voltage applied to the word line in order to secure the static noise margin of the memory cell when being valid. The detection circuit has a replica memory cell configured so as to make data retention ability lower than that of memory cell. The detection circuit detects the static noise margin of the memory cell in a pseudo manner by using the replica memory cell, and switches the validation/invalidation of the read assist circuit depending on a detection result.

According to the above embodiment, the increase of the access time with the read assist can efficiently suppressed in the semiconductor device including the SRAM.

### BRIEF DESCRIPTION OF THE DRAWINGS

FIG. 1 is a block diagram showing an outline configuration example of a semiconductor device according to a first embodiment.

FIG. 2 is a block diagram showing an outline configuration example of a volatile memory in FIG. 1.

FIG. 3 is a circuit diagram showing a configuration example of a memory cell in FIG. 2.

FIG. 4 is a block diagram showing an outline configuration example of an SNM detection circuit in FIG. 1.

FIG. 5 is a schematic diagram for explaining an operating example of a replica memory cell in FIG. 4.

FIG. 6 is a schematic drawing for explaining an effect due to using the replica memory cell in FIG. 4.

FIG. 7 is a schematic diagram showing an outline operating example of the SNM detection circuit in FIG. 4.

FIG. 8 is a circuit drawing showing a more detailed configuration example of the SNM detection circuit in FIG. 4.

FIG. 9 is a timing chart showing the operating example of the SNM detection circuit in FIG. 8.

FIG. 10A is a view showing one example of respective different components of the replica memory cell in FIG. 4.

FIG. 10B is a view showing one example of respective different components of the replica memory cell in FIG. 4.

FIG. 10C is a view showing one example of respective different components of the replica memory cell in FIG. 4.

FIG. 10D is a view showing one example of respective different components of the replica memory cell in FIG. 4.

FIG. 10E is a view showing one example of respective different components of the replica memory cell in FIG. 4.

FIG. 11 is a schematic diagram showing an arrangement configuration example of the SNM detection circuit in FIG. 2.

FIG. 12 is a schematic diagram showing another arrangement configuration example of the SNM detection circuit in FIG. 2.

FIG. 13 is a circuit diagram showing a more detailed configuration example of the SNM detection shown by FIG. 4 in a semiconductor device according to a second embodiment.

FIG. 14 is a timing chart showing a schematic operating example of the SNM detection circuit in FIG. 13.

FIG. 15 is circuit diagram showing a detailed configuration example different from that of the SNM detection circuit of FIG. 8 in a semiconductor device according to a third embodiment.

FIG. 16 is a truth table showing an operating example of a majority determination circuit in FIG. 15.

FIG. 17 is a schematic diagram showing an application example to a write assist of an SNM detection circuit in a semiconductor device according to a fourth embodiment.

FIG. 18 is a view showing an operating example of a write assist circuit in FIG. 17.

FIG. 19 is a diagram for explaining a static noise margin (SNM) of the memory cell shown by FIG. 3.

FIG. 20 is a view showing one example of various characteristics of the static noise margin (SNM).

FIG. 21 is a view showing the operating example of the read assist circuit in FIG. 2 and one example of a problem relative to the read assist.

### DETAILED DESCRIPTION

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle, and the number larger or smaller than the specified number is also applicable.

Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

In addition, in the embodiments later described, a p-channel type MOSFET (Metal Oxide Semiconductor Field Effect Transistor) and an n-channel type MOSFET are called a pMOS transistor an nMOS transistor, respectively. and Hereinafter, the embodiments of the present invention will be detailed based the drawings. Note that throughout all the figures for explaining the embodiments, the same reference numerals are denoted to the same members in principle, and its repetitive explanation will be omitted.

### First Embodiment

### Outline of Semiconductor Device

FIG. 1 is a block diagram showing an outline configuration example of a semiconductor device according to a first embodiment. A semiconductor device DEV shown by FIG. 1 is, for example, a System on Chip (SoC) configured by one semiconductor chip or is a microcontroller and the like. The semiconductor device DEV has a processor PRC, a volatile memory RAM, a non-volatile memory NVM, various peripheral circuits PERI, and buses connecting them to one another. In addition, the semiconductor device DEV has a power supply circuit PWG, a clock generation circuit CLKG, and the like.

The volatile memory RAM includes at least a SRAM. The non-volatile memory NVM is, for example, a Magnetoresistive Random Access Memory (MRAM), a flash memory, or the like. The processor PRC includes a Central Processing Unit (CPU) and, in addition thereto, can also include a Digital Signal Processor (DSP), Graphics Processing Unit (GPU), and the like. The processor PRC executes a predetermined program(s) memorized in the MRAM or copied to the volatile memory RAM from the flash memory etc. At this time, the processor PRC can use the SRAM as a work memory.

The various peripheral circuits FEPI are circuits depending on functions of the semiconductor device DEV. As the various peripheral circuits PERI, for example, an analog/digital converter, digital/analog converter, a serial/parallel interface, a serial communication circuit, an external memory interface, and the like are given. The power supply circuit PWG inputs a non-shown external power supply, and generates various power supply voltages including an SRAM power supply voltage VDD. The clock generation circuit CLKG uses a Phase Locked Loop (PLL) circuit and the like to generate various clock signals including an SRAM clock signal CLK.

### Outline of Volatile Memory (SRAM)

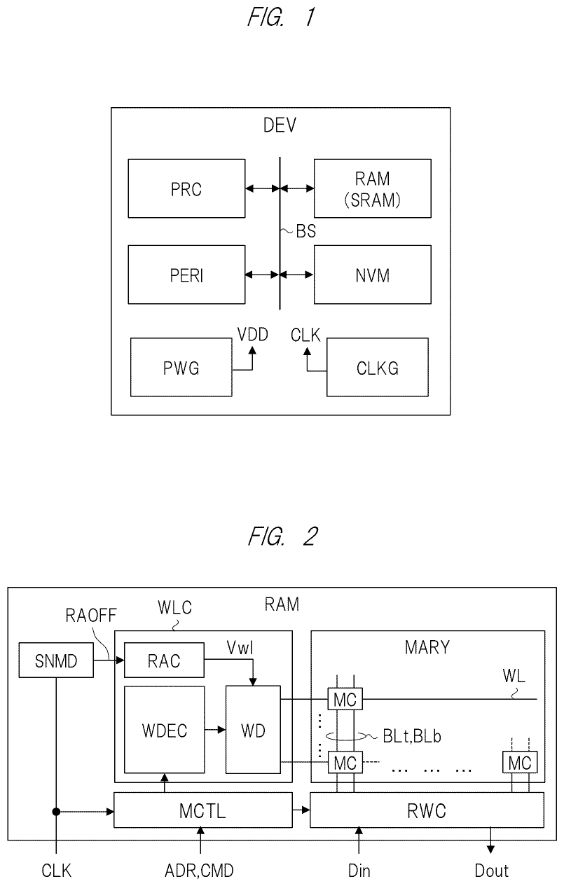

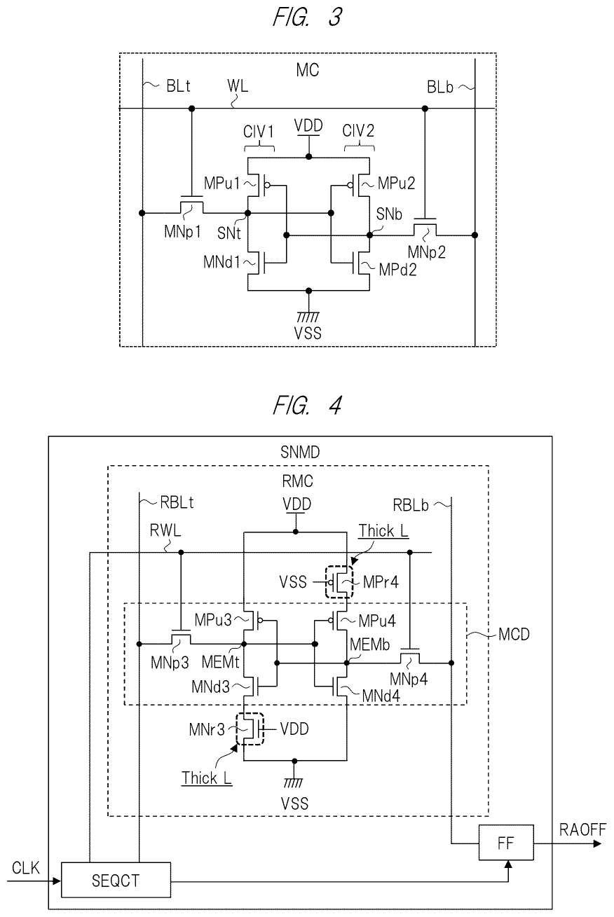

FIG. 2 is a block drawing showing an outline configuration example of a volatile memory RAM in FIG. 1. FIG. 3 is a circuit diagram showing a configuration example of a memory cell MC in FIG. 2. The volatile memory RAM shown in FIG. 2, specifically, the SRAM has a memory array MARY, a word line control circuit WLC, a read/write circuit RWC, a memory control circuit MCTL, and further a static noise margin detection circuit SNMD. In the specification, a static noise margin is abbreviated as an SNM in some cases.

The memory array MARY has a word line WL, a bit line pair (BLt, BLb) composed of complementary bit lines BLt, BLb, and a memory cell MC connected to the word line WL and the bit line pair (BLt, BLb). Specifically, the memory array MARY is provided with a plurality of word lines WL and a plurality of bit line pairs (BLt, BLb), and the memory cell MC is provided at a point intersecting with each word line WL and each bit line pair (BLt, BLb).

The memory control circuit MCTL inputs a clock signal CLK, an address signal ADR, and a command signal CMD, and controls the word line control circuit WLC and the read/write circuit RWC depending on their inputted contents. For example, a chip selection signal CS, a write enable signal WE, and the like can be included in the command signal CMD.

The word line control circuit WLC has a word decoder circuit WDEC, a word driver circuit WD, and a read assist circuit RAC. The word decoder circuit WDEC decodes the address signal ADR inputted via the memory control circuit MCTL, thereby selecting any of the plurality of word lines WL. The word driver circuit WD uses a word line voltage Vwl to activate the selected word line WL.

The read assist circuit RAC is configured so as to be capable of switching on/off, that is, validation/invalidation based on a read assist off signal RAOFF. For example, when the read assist off signal RAOFF is at a “H” level or a “1” level, the read assist circuit RAC is off, that is, invalid. Meanwhile, when the read assist off signal RAOFF is at a “L” level or a “0” level, the read assist circuit RAC is on, that is, valid.

The read assist circuit RAC lowers the word line voltage Vwl applied to the word line WL only by a predetermined amount when being valid based on the read assist off signal RAOFF. Consequently, the read assist circuit RAC secures the SNM of the memory cell MC. The static noise margin (SNM) detection circuit SNMD outputs the read assist off signal RAOFF. Note that details of the SNMD detection circuit SNMD will be explained later.

The read/write circuit RWC performs a write access or a read access, via the bit line pair (BLt, BLb), to the memory cell MC connected to the selected word line WL or, additionally thereto, the further selected memory cell MC based an instruction from the memory control circuit MCTL among them. At a time of the write access, the read/write circuit RWC writes an input date signal Din into the memory cell MC to be an object. At a time of the read access, the read/write circuit RWC reads an output data signal Dout from the memory cell to be an object.

More specifically, the read/write circuit RWC has, for example, a column selection circuit, a sense amplifier circuit, a write buffer circuit, and the like. The column selection circuit selects the part bit line pair (BLt, BLb) among the plurality of bit line pairs (BLt, BLb) based on the instruction from the memory control circuit MCTL. The write buffer circuit drives the selected bit line pair (BLt, BLb) based on the input data signal Din. The sense amplifier circuit amplifies a signal read from the selected bit line pair (BLt, BLb), and outputs it as the output date signal Dout to outside.

As shown in FIG. 3, the memory cell MC, that is, the SRAM memory cell has two pMOS transistors MPu1, MPu2, and four nMOS transistors MNd1, MNd2, MNp1, MNp2. The pMOS transistors MPu1, MPu2 are pull-up transistors for pulling up memory nodes SNt, SNb to the power supply voltage VDD, respectively. The nMOS transistors MNd1, MNd2 are pull-down transistors for pulling down the memory nodes SNt, SNb to the ground voltage Vss, respectively.

The nMOS transistors MNp1, MNp2 are respectively pass gate transistors for connecting the memory nodes SNt, SNb to the bit line pair (BLt, BLb) when the word line WL is activated. The nMOS transistor NMp1 connects a normal-rotation (True)-side memory node SNt to one of the bit line pair (BLt, BLb), here, the normal-rotation-side bit line BLt. The nMOS transistor MNp2 connects a reverse (Bar)-side memory node SNb to the reverse-side bit line BLb that is the other of the bit line pair (BLt, BLb).

The pMOS transistor MPu1 and the nMOS transistor MNd1 configurate a CMOS inverter circuit CIV1 whose input is the reverse-side memory node SNb and whose output is the normal-rotation-side memory node SNt. Meanwhile, pMOS transistor MPu2 and the nMOS transistor MNd2 configure a CMOS inverter circuit CIV2 whose input is the normal-rotation-side memory node SNt and whose output is the reverse-side memory node SNb. Consequently, a CMOS latch circuit is configurated.

### Regarding Static Noise Margin (SNM)

FIG. 19 is a drawing for explaining a static noise margin (SNM) of the memory cell MC shown in FIG. 3. FIG. 19 shows one example of input characteristics of the CMOS inverter circuits CIV1, CIV2, a voltage of the normal-rotation-side memory node SNt being set as a vertical axis, a voltage of the reverse-side memory node SNb being set as a horizontal axis. Each of the input characteristics is called a butterfly curve. As shown in FIG. 19, the SNM is defined as an interval between the two butterfly curves. The SNM become enough as this interval is large.

The SNM brings a problem, particularly, at the time of the read access. As a specific example, it is assumed that the read access is performed to the memory cell MC which holds the “L” level at the normal-rotation-side memory node SNt and the H” level at the reverse-side memory node SNb. In the read access, for example, the bit line pair (BLt, BLb) are both pre-charged to the “H” level, and then the word line WL is activated. At this time, disturb, that is, noise occurs via the nMOS transistor MNp1 from the bit line BLt at the “H” level to the memory node SNt at the “L” level.

When the SNM lacks, that is, when the interval shown by FIG. 19 is small, the memory node SNb is reversed from the “H” level to the “L” level by this disturb and, at the same time, the memory node SNt may also be reversed from the “L” level to the “H” level. Note that the interval shown by FIG. 19 can usually be made small along with the miniaturization. For this reason, such a disturb problem may be made more remarkable as the miniaturization advances.

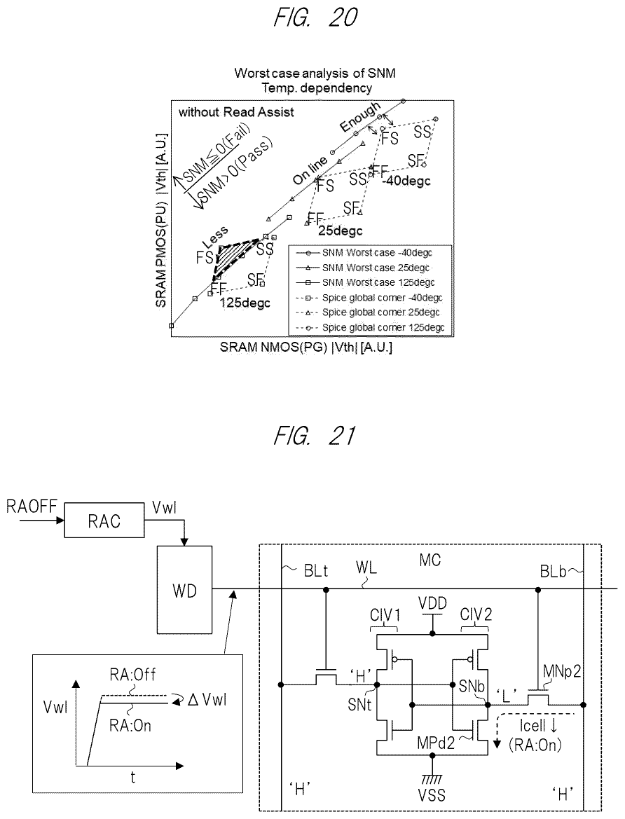

FIG. 20 is a view showing one example of various characteristics of the static noise margin (SNM). FIG. 20 shows a relative example between a threshold voltage of the pass gate transistor (PG) in FIG. 3 and a threshold voltage of a pull-up transistor (PU). An upper-left region obtained by using a right-should-rising boundary line as a reference is a region where the SNM lacks. Meanwhile, the SNM becomes enough as being more remote in a down-right direction by using the boundary line as a reference.

As shown in FIG. 20, the SNM problem becomes apparent as temperature is higher. In other words, the SNM problem becomes less likely to occur as temperature is lower. In addition, with the manufacturing variations, the SNM problem increases due to an FS condition and decreases due to an SF condition. For example, in the FS condition, a speed of the nMOS transistor is “Fast” with a low threshold value, and a speed of the pMOS transistor is “Slow” with a high threshold value.

FIG. 21 is a view showing one example of an operating example of the read assist circuit RAC in FIG. 2 and a problem relative to the read assist. When being on, that is, valid based on the read assist off signal RAOFF, the read assist circuit RAC lowers the word line voltage Vwl by a decent rate ΔVwl. For example, the decent rate ΔVwl is about a several tents mV with respect to the word line voltage Vwl of about 1.0 V at a normal time.

In this way, in the above specific example, lowering the word line voltage Vwl makes it possible to make smaller a disturb amount via the nMOS transistor MNp1 to the memory node SNt from the bit line BLt. As a result, the SNM of the memory cell MC can be secured. However, as its side effects, a memory cell current Icell at the time of the read access becomes small. In an example shown by FIG. 21, the memory cell current Icell flows to the memory node SNb maintaining the “L” level from the bit line BLb pre-charged to the “H” level via the nMOS transistor MNp2 in which On resistance is increased.

In addition, at the time of the read access, a potential difference of the bit line pair (BLt, BLb) is amplified by the sense amplifier circuit after passing a predetermined waiting time from the activation of the word line WL. As the memory cell current Icell becomes small, a waiting time required for obtaining the sufficient potential difference become long. As a result, an access time of the SRAM increases and, simultaneously, a processing time of the processor PRC can be lowered. In addition, such a problem about the increase of the access time brings, particularly, an increase of the threshold voltage of the MOS transistor, and eventually can be made more remarkable at a time of low temperature at which the speed can be lowered. Therefore, the SNM detection circuit SNMD shown by FIG. 1 is provided.

### Outline of SNM Detection Circuit

FIG. 4 is a block diagram showing an outline configuration example of the SNM detection circuit in FIG. 1. FIG. 5 is a schematic diagram for explaining an operating example of a replica memory cell RMC in FIG. 4. The SNM detection circuit SNMD shown by FIG. 4 has a replica memory cell RMC, a sequence control circuit SEQCT, and a latch circuit FF. The replica memory cell RMC has a replica word line RWL, a replica bit line pair (RBLt, RBLb), and a dummy memory cell MCD connected to them. The dummy memory cell MCD has a configuration obtained by a copy of the normal memory cell MC shown by FIG. 3.

That is, the dummy memory cell MCD has two pMOS transistors MPu3, MPu4, four nMOS transistors MNd3, MNd4, MNp3, MNp4, and complementary memory nodes MEMt, MEMb. Each of the pMOS transistors MPu3, MPu4 pulls up the complementary memory nodes MEMt, MEMb to a power supply voltage (high-potential-side power supply voltage) VDD. The pMOS transistor (first pull-up transistor) MPu3 pulls up the normal-rotation-side memory node MEMt. The pMOS transistor (second pull-up transistor) MPu4 pulls up the reverse-side memory node MEMb.

Each of the nMOS transistors MNd3, MNd4 pulls down the complementary memory nodes MEMt, MEMb to the ground voltage (low-potential-side power supply voltage) VSS. The nMOS transistor (first pull-down transistor) MNd3 pulls down the norma-rotation-side memory node MEMt. The nMOS transistor (second pull-down transistor) MNd4 pulls down the reverse-side memory node MEMb.

Each of the nMOS transistors MNp3, MNp4 connects the complementary memory nodes MEMt, MEMb to the complementary replica word lines (RBLt, RBLb) when the replica word line RWL is activated. The nMOS transistor (first pass gate transistor) MNp3 connects the normal-rotation-side memory node MEMt to the normal-rotation-side replica bit line RBLt. The nMOS transistor (second pass gate transistor) MNp4 connects the reverse-side memory node MEMb to the reverse-side replica bit line RBLb.

Here, the replica memory cell RMC is configurated so as to be lower in data retention ability than the normal memory cell Mc. As one method thereof, the replica memory cell RMC shown by FIG. 4 has an nMOS transistor MNr3 and a pMOS transistor MPr4. The nMOS transistor (first limiting transistor) MNr3 is inserted into a current path between the nMOS transistor MNd3 and the ground voltage VSS. The pMOS transistor (second limiting transistor) MPr4 is inserted into a current path between the pMOS transistor MPu4 and the power supply voltage VDD.

The nMOS transistor MNr3 has a gate length (L) larger than that of the nMOS transistor MNd3, in other words, has a gate electrode thick in width. The nMOS transistor MNr3 always becomes on by applying the power supply voltage VDD to the gate. Similarly, the pMOS transistor MPr4 has a gate length (L) larger than that of the pMOS transistor MPu4, in other words, has a gate electrode thick in width. The pMOS transistor MPr4 always becomes on by applying the ground voltage VSS to the gate.

In FIG. 5, the replica memory cell RMC has the nMOS transistor MNr3 for limiting a pull-down current, so that the retention ability at the “L” level in the normal-rotation-side memory node MEMt becomes low. Similarly, the replica memory cell RMC has the pMOS transistor MPr4 for limiting a pull-up current, so that the retention ability at the “H” level in the reverse-side memory node MEMb becomes low. As a result, in the replica memory cell RMC, when the disturb at the “H” level, that is, noise is applied to the normal-rotation-side replica bit line RBLt, date inversion, that is, the lack of the SNM easily occurs in comparison with the normal memory cell.

Returning FIG. 4, the SNM detection circuit SNMD uses such a replica memory cell RMC to detect the SNM of the normal memory cell MC in a pseudo manner. Further, the SNM detection circuit SNMD switches on/off of the read assist circuit RAC, that is, validation/invalidation thereof according to its detection result by using the read assist off signal RAOFF. At this time, the sequence control circuit SEQCT controls various sequences depending on the detection of the SNM that uses the replica memory cell RMC. Its details will be described later, but the sequence control circuit SEQCT performs an initializing operation and a detecting operation per clock cycle based on the inputted clock signal CLK.

The latch circuit FF, in other words, a flip-flop circuit holds the detection result obtained by using the replica memory cell RMC. Specifically, the latch circuit FF latches a logical level of the reverse-side replica bit line RBLb depending on the trigger signal from the sequence control circuit SEQCT. Further, the latch circuit FF outputs the latched logical level as the read assist off signal RAOFF.

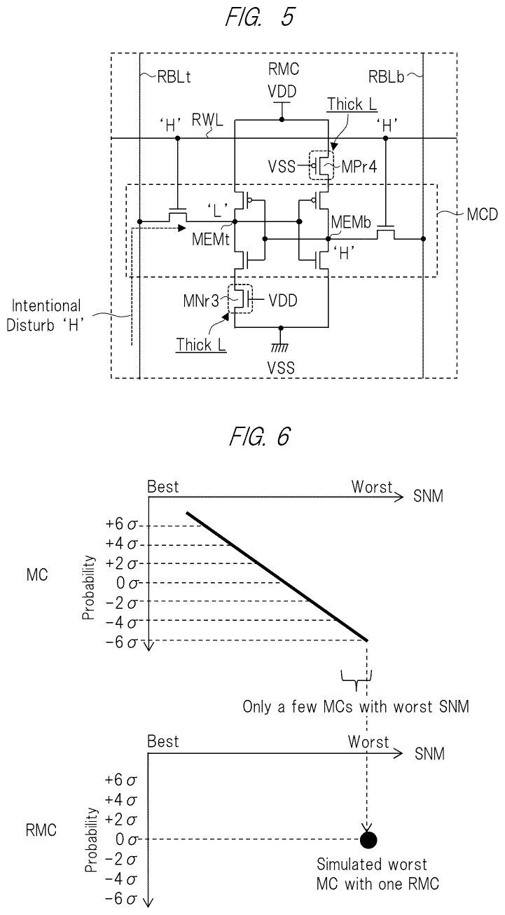

FIG. 6 is a schematical diagram for explaining an effect about using the replica memory cell RMC in FIG. 4. In the normal memory cell MC, the memory cell MC in which the SNM becomes worst, that is, in which the lack of the SNM can happen occurs at an existence probability of 5σ to 6σ with the manufacturing variations, that is, random variations. Consequently, it is difficult to use the normal memory cell MC to determine whether the SNM is good or bad.

The data retention ability of the replica memory cel RMC reflects, for example, the data retention ability of the memory cell MC which happens at the existence probability of 5σ to 6σ, and is determined to such ability as to add a margin in a further worst direction. That is, in a case of FIG. 4, the gate length (L) of the limiting transistor (MNr3, MPr4) is determined so as to have such data retention ability. Consequently, the SNM of the memory cell MC that is worst among many memory cells MC can be detected in a pseudo manner by using one replica memory cell RMC.

However, at this time, it is premised that the replica memory cell RMC itself is hardly affected by the manufacturing variations. Therefore, the replica memory cell RMC is preferably configurated by using the transistor whose gate length (L) or gate width (W) is larger than that of the transistor configurating the normal memory cell MC. Usually, the affection of the manufacturing variations becomes smaller as the length (L) or gate width (W) is larger.

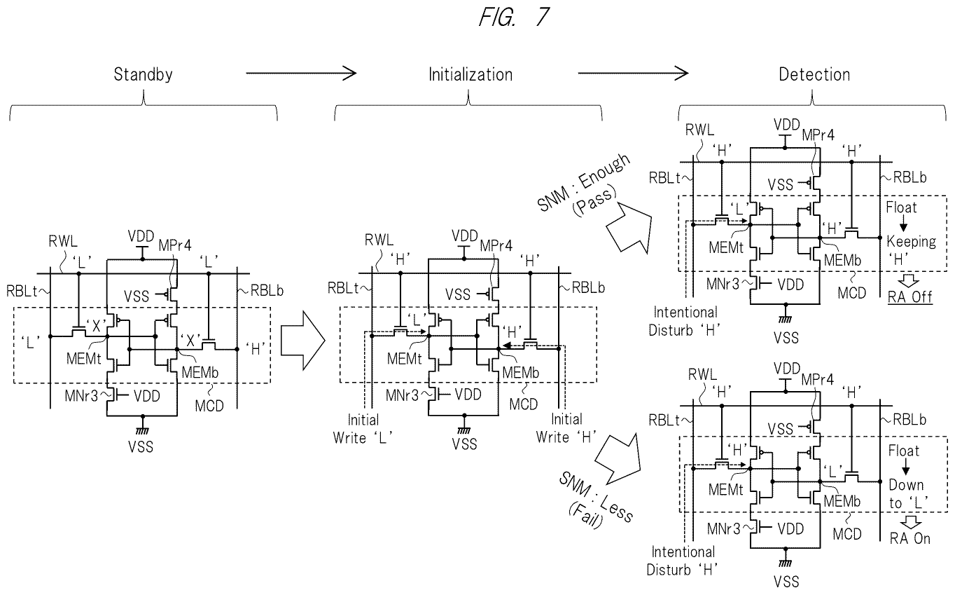

FIG. 7 is a schematic diagram showing an outline operation example of the SNM detection circuit SNMD in FIG. 4. As shown in FIG. 7, the SNM detection circuit SNMD performs a series of operations composed of a standby operation, an initializing operation, and a detecting operation. Specifically, the SNM detection circuit SNMD performs the initializing operation and the detecting operation according to the clock signal CLK, and then returns to the standby operation. The sequence control circuit SEQCT controls the entire SNM detection circuit SNMD so that such a series of operations is performed.

In the standby operation, the sequence control circuit SEQCT controls the replica word line RWL to an inactivation state, that is, at the “L” level. As a result, the memory nodes MEMt, MEMb retain date at an indeterminate “X” level, specifically, retains the data at the previous clock cycle. Continuously, in the initializing operation, the sequence control circuit SEQCT activates the replica word line RWL, that is, make it at the “H” level. Further, the sequence control circuit SEQCT writes the “L” level and the “H” level in the normal-rotation-side memory node MEMt and the reverse-side memory node MEMb via the replica bit line pair (RBLt, RBLb), respectively.

Next, in the detecting operation, the sequence control circuit SEQCT controls the reverse-side replica bit line RBLb in the floating state with the replica word line RWL activated and, simultaneously, applies the normal-rotation-side replica bit line RBLt to the “H” level. Then, the sequence control circuit SEQCT causes the latch circuit FF to latch the logical level of the reverse-side replica bit line RBLb. Consequently, the SNM detection circuit SNMD makes detection about whether the reverse-side replica bit line RBLb is in a pass state capable of maintaining the “H” level or in a fail state reversed to the “L” level.

The pass state is a state in which the SNM is sufficient, and the fail state is a state in which the SNM lacks. In a case of the pass state, the latch circuit FF outputs the “H” level, that is, an assert level as the read assist off signal RAOFF. Consequently, the SNM detection circuit SNMD makes the read assist circuit RAC in an off state, that is, makes it invalidate. Meanwhile, in a case of the fail state, the latch circuit FF outputs the “L” level, that is, an negate level as the read assist off signal RAOFF. Consequently, the SNM detection circuit SNMD makes the read assist circuit RAC in an on state, that is, validates it.

Here, as known from FIG. 20 described above, the detection result of the SNM detection circuit SNMD easily becomes the pass state as temperature is lower, and easily becomes the fail state as the temperature is higher. Meanwhile, as described in FIG. 21, the access time easily increases as the temperature lower. Therefore, it is advantageous to use the SNM detection circuit SNMD to invalidate the read assist circuit RAC, particularly, at low temperature. Consequently, particularly, the increase of the access time with the read assist at the low temperature can be suppressed.

In addition, the on/off of the read assist circuit RAC can be controlled by using the SNM detection circuit SNMD without using a PVT monitor sensor, which includes a process monitor circuit (PMC) and a bandgap reference (BGR) circuit, as disclosed in Non-Patent Document 2. Generally, the PVT monitor sensor is configurated by using a high breakdown voltage transistor, so that its area increases in comparison with that of the SNM detection circuit SNMD. For example, a circuit area of the PVT monitor sensor can also be made larger ten times more than that of the SNM detection circuit SNMD.

Further, the PVT monitor sensor takes some times, for example, can take microsecond order until operations of the BGR circuit and the like are stable. Then, for example, when the semiconductor device DEV returns to a normal mode from a sleeve mode, it takes some times in order to determine the validation/invalidation of the read assist circuit RAC.

In addition, when a waiting time is small, the validation/invalidation can be correctly determined, so that the read assist circuit RAC requires be validated even at the low temperature.

Meanwhile, by using the SNM detection circuit SNMD, the detection result of the SNM can be obtained at a period of the clock cycle based on the clock signal, that is, at a period of an access to the SRAM. Consequently, even when the semiconductor device DEV returns to the normal mode from the sleeve mode, the correct detection result can be obtained, particularly, without requiring the waiting time. From the above description, by using the SNM detection circuit SNMD, the increase of the access time with the read assist can efficiently be suppressed. Further, a method of detecting the SNM in a pseudo manner may determine whether the read assist is necessary or unnecessary more accurately than a method disclosed in Non-Patent Document 2.

### Detail of SNM Detection Circuit

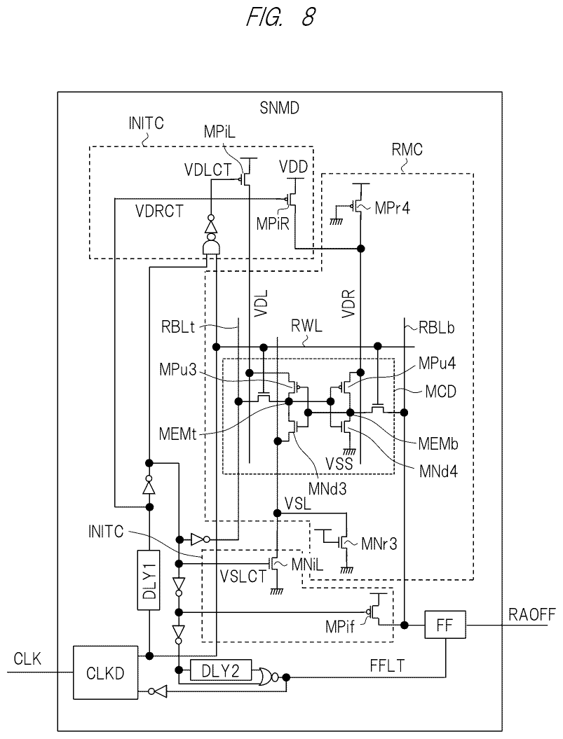

FIG. 8 is a circuit diagram showing a more detailed configuration example of the SNM detection circuit SNMD in FIG. 4. The SNM detection circuit SNMD shown by FIG. 8 has an initialization circuit INITC, a clock driver circuit CLKD, and various logic gates including delay circuits DLY1, DLY2 in addition to the replica memory cell RMC and the latch circuit FF shown in FIG. 8. The clock driver circuit CLKD and the various logic gates correspond to the sequence control circuit SEQCT of FIG. 4.

As described in FIGS. 4 and 7, in the replica memory cell RMC, the “L” level and the “H” level are written into the normal-rotation-side memory node MEMt and the reverse-side memory node MEMb at the initializing operation, respectively. However, the replica memory cell RMC is configured so that the data retention ability at the “L” level in the memory node MEMt and the data retention ability at the “H” level in the memory node MEMb become low. Consequently, in the initializing operation, it may be different to write themselves the “L” level and the “H” level in the complementary memory nodes MEMt, MEMb.

Therefore, in FIG. 8, the initialization circuit INITC used in the initializing operation is provided. Here, for convenience of description, the initialization circuit INIT is shown by dispersing at two places. The initialization circuit INITC has an nMOS transistor MNiL, a pMOS transistor MPif, and two pMOS transistors MpiL, MPiR.

In the nMOS transistor (first initial writing transistor) MNiL, a source-drain path is connected in parallel to the nMOS transistor (first limiting transistor) MNr3 in the replica memory cell RMC. The nMOS transistor MNiL has a gate length shorter than that of the nMOS transistor MNr3, and is configured so that the sufficient pull-down current flows. The nMOS transistor MNiL becomes the on state at the time of the initializing operation based on the control signal VSLCT and becomes the off state at the time of the detecting operation, thereby controlling the voltage VSL.

In the pMOS transistor (second initial writing transistor) MPiR, a source-drain path is connected in parallel to the pMOS transistor (second limiting transistor) MPr4 in the replica memory cell RMC. The pMOS transistor MPiR has a gate length longer than that of the pMOS transistor MPr4 and is configured so that the sufficient pull-up current flows. The pMOS transistor MPiR becomes the on state at the time of the initializing operation based on the control signal VDRCT and becomes the off state at the time of the detecting operation, thereby controlling the voltage VDL.

The pMOS transistor (third initial writing transistor) MpiL is inserted into a current path between the pMOS transistor (first pull-up transistor) MPu3 in the replica memory cell RMC and the power supply voltage VDD. The pMOS transistor MpiL becomes the off state at the time of initializing operation based on the control signal VDCT and becomes the off state at the time of the detecting operation, thereby writing more accurately the “L” level in the memory node MEMt.

In this way, by providing the nMOS transistor MNiL and the pMOS transistor MPiR, affection of current limit due to the nMOS transistor MNr3 and the pMOS transistor MPr4 can be excluded. Further, at the time of the initializing operation, by using the pMOS transistor MPiL to block a connection path between the norma-rotation-side memory node MEMt and the power supply voltage VDD, the “L” level is written more accurately in the memory node MEMt.

Note that the pMOS transistor MPif is an initial writing and floating transistor connected between the reverse-side replica bit line RBLb and the power supply voltage VDD. The pMOS transistor MPif is turned on/off based on a reverse signal of the control signal VSLCT similarly to the nMOS transistor MNiL. Consequently, the pMOS transistor MPif becomes the on state at the time of the initializing operation, thereby driving the replica bit line RBLb to the “H” level. Meanwhile, the pMOS transistor MPif becomes the off state at the time of the detecting operation, thereby making the replica bit line RBLb in the floating state.

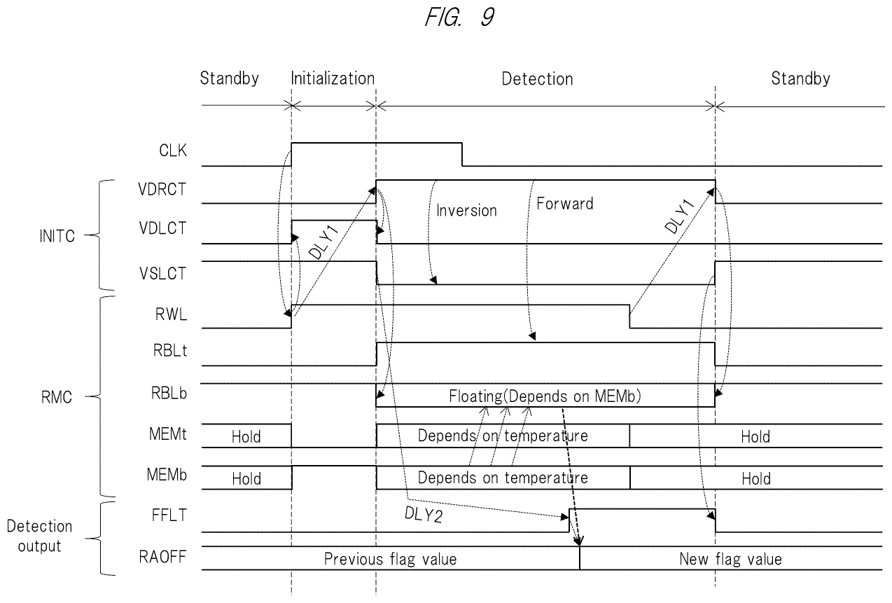

FIG. 9 is a timing chart showing an operation example of the SNM detection circuit SMND. As shown in FIG. 9, the SNM detection circuit SNMD performs the initializing operation and the detecting operation according to the clock signal CLK, and returns to the standby operation. The clock driver circuit CLKD reacts a rise of the clock signal CLK and generates an “H” pulse signal for activating the replica word line RWL. In addition, by delaying the pulse signal through the delay circuit DLY1, the control signal VDRCT is generated.

An interval of the initializing operation is determined by an interval from a rise of the replica word line RWL to a rise of the control signal DVRCT. That is, the interval of the initializing operation is determined based on a delay time of the delay circuit DLY1. In addition, a length of the interval of the initializing operation is determined based on a pulse width of a “H” pulse signal of the replica word line RWL.

The control signal VDRCT becomes the “L” level in the interval of the initializing operation, and becomes the “H” level in the interval of the detecting operation. Along with this, the pMOS transistor MPiR supplies the power supply voltage VDD to the pull-up transistor (MPu4) in the interval of the initializing operation, and blocks the voltage in the interval of the detecting operation. Since the supply of the voltage is blocked, the data retention ability of the replica memory cell RMC is limited by the pMOS transistor MPr4.

The control signal VDLCT becomes the “H” level in an interval from the rise of the replica word line RWL to the rise of the control signal VDRCT, that is, in the interval of the initializing operation. Along with this, the pMOS transistor MpiL blocks the supply of the power supply voltage VDD to the pull-up transistor (MPu3) in the interval of the initializing operation, and resumes the supply of the voltage in the interval of the detecting operation.

The control signal VSLCT is an inversion signal of the control signal VDRCT. Along with this, the nMOS transistor MNiL supplies the power supply voltage VDD to the pull-down transistor (MNd3) in the interval of the initializing operation, and blocks the supply of the voltage in the interval of the detecting operation. Since the supply of the voltage is blocked, the data retention ability of the replica memory cell RMC is limited by the nMOS transistor MNr3.

In addition, the normal-rotation-side replica bit line RBLt is driven based on the control signal VDRCT. Therefore, since driven to the “L” level in the interval of the initializing operation, the replica bit line RBLt writes the “L” level in the memory node MEMt. Then, since transitioning to the “H” level at a time of transitioning to the detecting operation, the replica bit line RBLt applies the disturb at the “H” level to the memory node MEMt in which the “L” level is written.

The reverse-side replica bit line RBLb is driven by the pMOS transistor MPif inputting the control signal VDRCT. Along with this, since driven to the “H” level in the interval of the initializing operation, the replica bit line RBLb writes the “H” level in the memory node MEMb. Then, the replica bit line RBLb become the floating state in the interval of the detecting operation. Consequently, the logic level of the replica bit line RBLb is determined by an SNM state depending on the temperature.

The latch signal FELT is generated by logically calculating the control signal VSLCT and a signal in which the control signal VSLCT is delayed by the delay circuit DLY2. Consequently, the latch circuit FFLT becomes the “H” pulse signal outputted after a delay time of the delay circuit DLY2 from start of the detecting operation. The latch circuit FF latches the logic data of the reverse-side replica bit line RBLb at the rise of the latch signal FFLT, and outputs it as the read assist off signal RAOFF.

### Detail of Replica Memory Cell

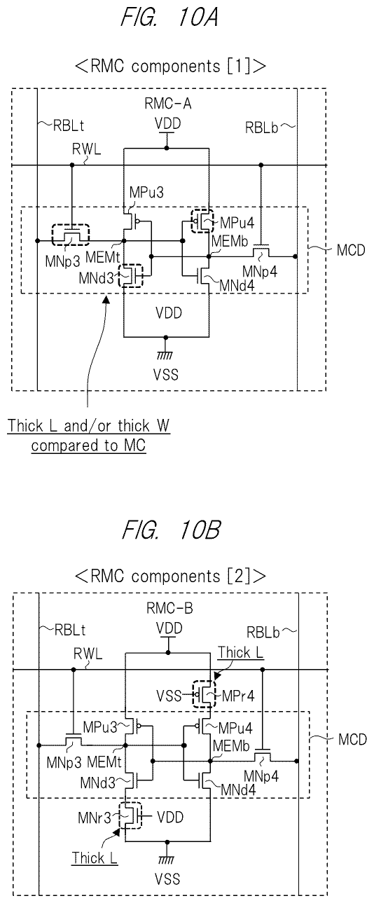

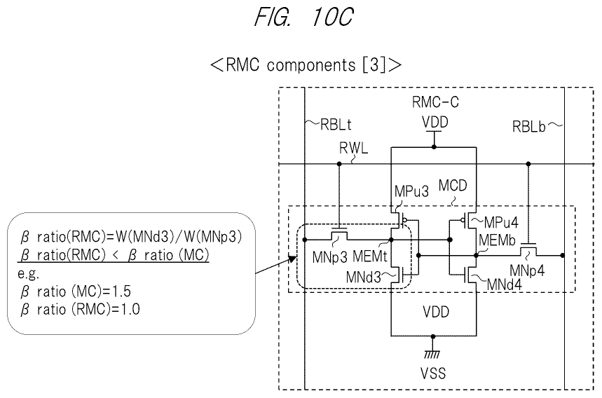

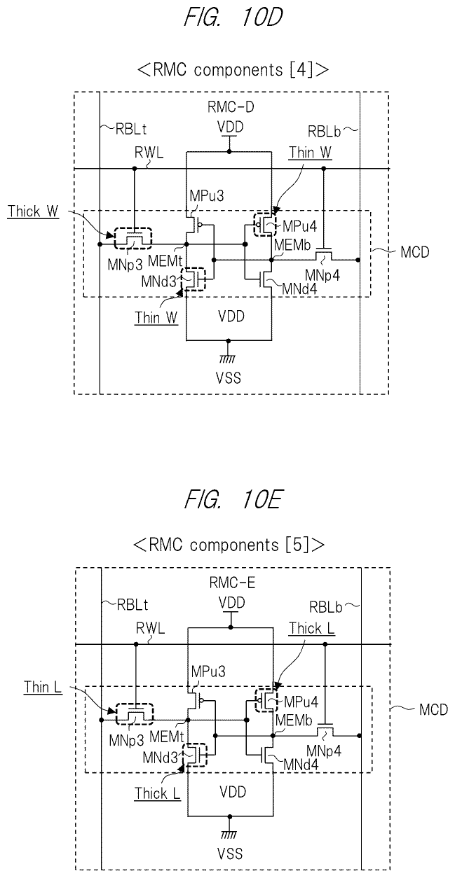

FIGS. 10A, 10B, 10C, 10D, and 10E are views showing respective examples of different components of the replica memory cell in FIG. 4. The replica memory cell RMC is configured by using at least one or more of Components [1] to [5] shown in FIGS. 10A to 10D. The replica memory cell RMC-A shown by FIG. 10A is configured by using a transistor that is larger in gate length (L) or gate width (W) than a transistor configuring the normal memory cell MC.

In other words, the replica memory cell RMC-A is configured on the whole by using a transistor whose horizontal width of vertical width of the gate electrode in a planer direction is thick. As one example, a size of the gate length (L) or gate width (W) of each transistor configuring the replica memory cell RMC-A may be more than twice of each transistor configuring the normal memory cell MC. Consequently, as described in FIG. 6, the affection of the manufacturing variations, that is, random variations can be reduced.

Meanwhile, Components [2] to [5] shown by FIGS. 10B to 10E are different from Component [1] shown in FIG. 4 for reducing the affection of the manufacturing variations, and elements for decreasing the data retention ability. Accordingly, for example, the replica memory cell RMC is preferably configured by combining any of Components [2] to [5] with Component [1].

As shown in FIG. 4, a replica memory cell RMC-B shown by FIG. 10B has the nMOS transistor (first limiting transistor) MNr3 and the pMOS transistor (second limiting transistor) MNr4. The nMOS transistor MNr3 is inserted into a current path between the nMOS transistor (first pull-down transistor) MNd3 and the ground voltage VSS. The pMOS transistor MPr4 is inserted into a current path between the pMOS transistor (second pull-up transistor) MPu4 and the power supply voltage VDD.

The nMOS transistor MNr3 has a gate length (L) larger than that of the nMOS transistor MNd3. The pMOS transistor MPr4 also has a gate length (L) larger than that of the pMOS transistor MPu4. As one example, the nMOS transistor MNr3 and the pMOS transistor MPr4 may has the gate lengths (L) five times larger than those of the nMOS transistor MNd3 and the pMOS transistor MPu4, respectively.

Here, in order to decrease the data retention ability, it is also considered to use the small gate width (W) instead of using the large gate length (L). However, in this case, using the short gate width is easily influenced by the manufacturing variations. Consequently, it is advantageous to use the large gate length (L). Note that the nMOS transistor MPr3 always becomes the on state by applying the power supply voltage VDD to the gate. The pMOS transistor MPr4 always becomes the ogn state by applying the gate to the ground voltage VSS, too.

In order to decrease the data retention ability, the replica memory cell RMC may use methods shown by FIGS. 10C to 10E without being limited to a method shown by FIG. 10B, that is, FIG. 4. In the FIGS. 10C to 10E, the replica memory cell RMC is configured so that relative drive ability between the respective transistors configuring the replica memory cell RMC is different from relative drive ability between the respective transistors configuring the normal memory cell MC. That is, the replica memory cell RMC is configured so that its balance of the drive ability is different from that of the normal memory cell MC.

In FIG. 10C, first, the β ratio is generally defined as an index simply representing a degree of the SNM in the SRAM memory cell. If it is assumed that the gate width of the nMOS transistor (first pass gate transistor) MNp3 is set as “W1” and the gate width of the nMOS transistor (first pull-down transistor) MNd3 is set as “W2”, the β ratio is given by “W2/W1”.

In the normal memory cell MC, the value of the β ratio is set at, for example, about 1.5 for securing the sufficient SNM. Meanwhile, the value of the β ratio in the replica memory cell RMC-C shown by FIG. 10C becomes small than the value of the β ratio of the normal memory cell MC. For example, the β ratio in the replica memory cell RMC-C may be about 1.0. Consequently, the data retention ability of the norma-rotation-side memory node MEMt at the “L” level is intentionally decreased with respect to the disturb at the “H” level from the normal-rotation-side replica bit line RBLt.

The replica memory cells RMC-D, RMC-E are different in the drive ability of the nMOS transistors MNp3, MNd3 and the pMOS transistor MPu4 in comparison with the relative drive ability of the normal memory cell MC. That is, here, they are configured so as to increase the drive ability of the nMOS transistor (first pull-down transistor) and MNp3 decrease the drive ability of the nMOS transistor (first pull-down transistor) MNd3. Further, they are configured so as to decrease the drive ability of the pMOS transistor (second pull-up transistor) MPu4.

This drive ability is adjusted by the gate width (W) in FIG. 10D and is adjusted by the gate length (L) in FIG. 10E. That is, in FIG. 10D, it is adjusted so that the gate width (W) of the nMOS transistor MNp3 becomes large, the gate width (W) of the nMOS transistor MNd3 becomes small, and the gate width (W) of the pMOS transistor MPu4 becomes small. In FIG. 10E, it is adjusted so that the gate length (L) of the nMOS transistor MNp3 becomes small, the gate length (L) of the nMOS transistor MNd3 becomes large, and the gate length (L) of the pMOS transistor MPu4 becomes large.

By such a configuration, the data retention ability of the normal-rotation-side memory node MEMt at the “L” level and the data retention ability of the reverse-side memory node MEMb at the “H” level are intentionally decreased with respect to the data retention ability at the “H” level from the normal-rotation-side replica bit line RBLt. Note that as described above, when the size of the transistor is decreased, the manufacturing variations are easily influenced. From this point of view, it is advantageous to combine Component [2] or Component [3] with Component [1]. In this case, for example, fine adjustment may be performed by further combining Component [4] or Component [5].

### Arrangement of SNM Detection Circuit

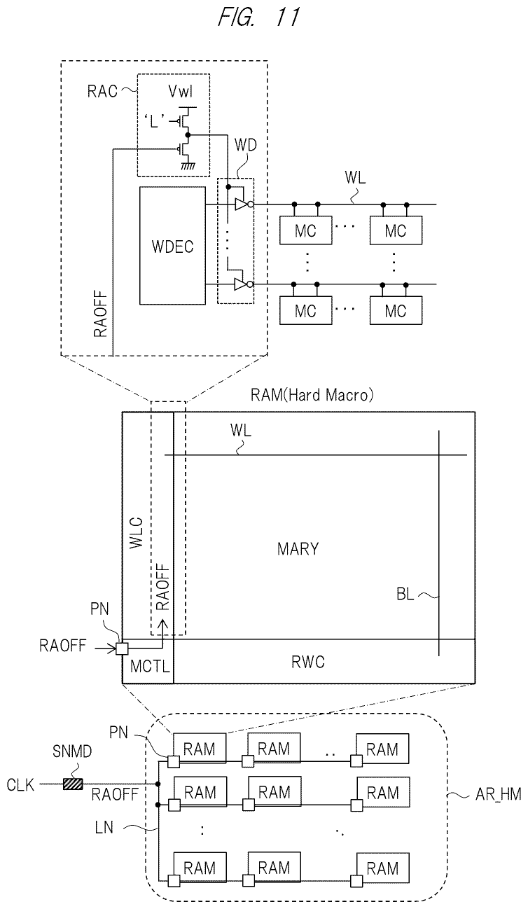

FIG. 11 is a schematic diagram showing an arrangement configuration example of the SNM detection circuit SNMD in FIG. 2. The volatile memory RAM shown by FIG. 11, specifically, the SRAM is configured by a hard macro(s). Then, in this example, a plurality of SRAMs configured by the hard macros are arranged in an arrangement region AR HM of the hard macros.

As described in FIG. 2, each SRAM has the memory array MARY, the word line control circuit WLC, the read/write circuit RWC, and the memory control circuit MCTL. In addition, the word line control circuit WLC has a word decoder circuit WDEC, a word driver circuit WD, and a read assist circuit RAC. The read assist circuit RAC supplies a word line voltage Vwl to the word driver circuit WD.

In this time, in an example shown by FIG. 11, when the read assist off signal RAOFF is in the “H” level, the read assist circuit RAC supplies the word line voltage Vwl, which is not step down, via one pMOS transistor. Meanwhile, when the read assist off signal RAOFF is in the “L” level, the read assist circuit RAC supplies the word line voltage Vwl, which is set down, based on an On-resistance ratio of two pMOS transistor.

Here, each SRAM configured by the hard macro has a switching terminal PN for switching an on/off, that is, validation/invalidation of the read assist circuit RAC. The detection circuit SNM SNMD is arranged outside the arrangement region AR HM of the hard macro, and is commonly connected to the switching terminal PN of each SRAM via a signal wiring LN. Generally, such a hard macro having the switching termina PN is widely used. A method shown in FIG. 11 may be new provided with the SNM detection circuit SNMD and use a wring to the switching terminal PN that the existing hard macro has.

In this way, commonly providing one SNM detection circuit SNMD to the plurality of hard macros I makes it possible to decrease overhead of a circuit area. Note that, for example, the number of the SNM detection circuit SNMDs is not limited to one, and may be two or more in consideration of a temperature distribution in a chip. In this case, for example, the arrangement region AR HM as shown in FIG. 11 is provided two or more in number, and the SNM detection circuit SNMD is provided near each of a plurality of arrangement regions AR HM.

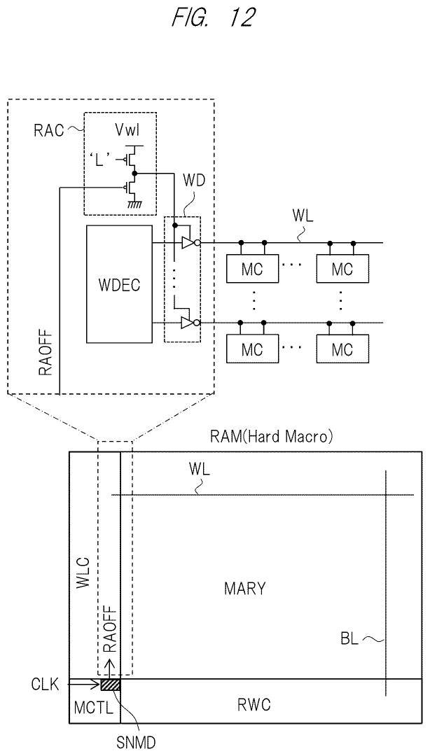

FIG. 12 is a schematic diagram showing another arrangement configuration example of the SNM detection circuit SNMD in FIG. 2. In FIG. 12, unlike a case of FIG. 11, the hard macro configurating the SRAM is built in the SNM detection circuit SNMD. In this example, the SNM detection circuit SNMD is one part of the memory control circuit MCTL. In a case of using such a method, for example, it is not required to separately implement the SNM detection circuit SNMD in performing an arrangement, a wiring, and the like of the semiconductor device DEV as shown in FIG. 1, and the hard macro has only to be implemented. Consequently, design of the semiconductor device DEV can be facilitated.

### Main Effects by First Embodiment

As described above, in the first embodiment, the replica memory cell configurated so that the data retention ability is decreased is used to detect the static noise margin (SNM) of the normal memory cell in a pseudo manner, and the SNM detection circuit for switching the validation/invalidation of the read assist circuit according to the detection result is provided. Consequently, representatively, the increase of the access time with the read assist can efficiently be suppressed in the semiconductor device including the SRAM.

More specifically, using the replica memory cell makes it possible to detect the SNM with a small area, and to perform the detection at a short time, for example, in the clock cycle. Thus, detecting the SNM makes it possible to invalid the read assist circuit, particularly, at the low temperature, and to suppress a decrease in a memory cell current with the read assist, eventually, the increase in the access time.

### Second Embodiment

### Details of SNM Detection Circuit

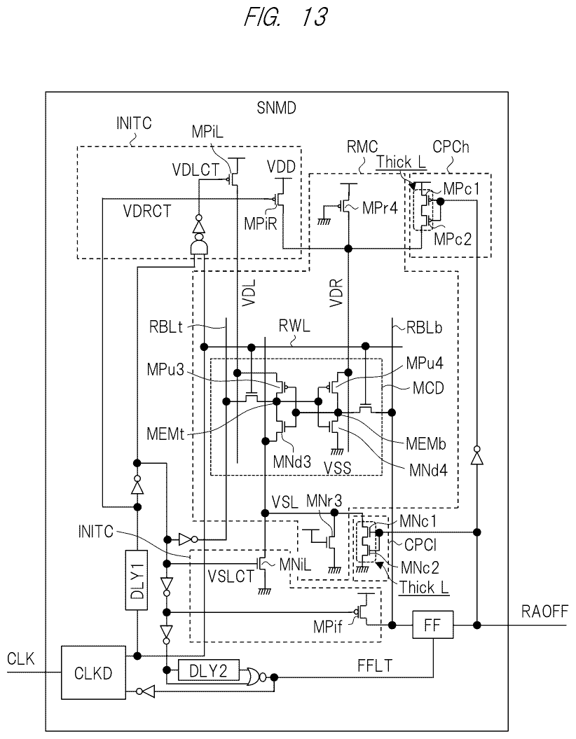

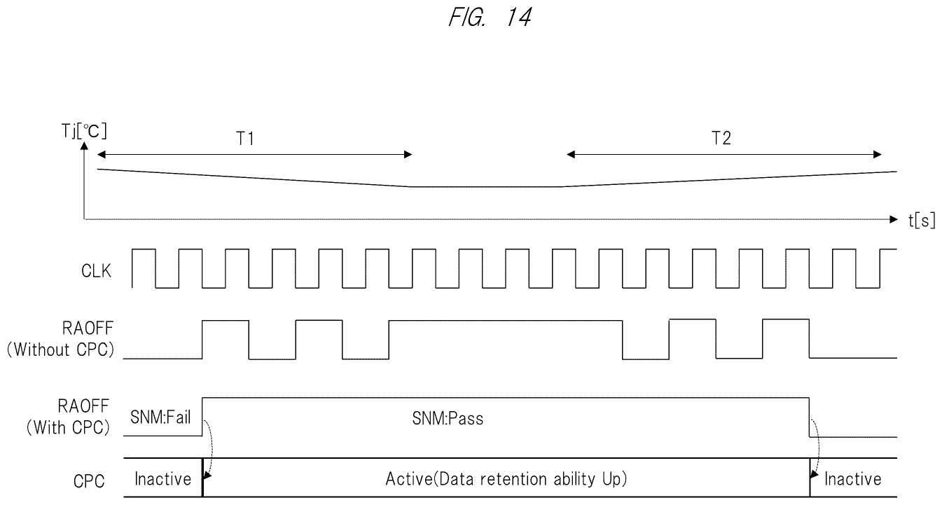

FIG. 13 is a circuit diagram showing a more detailed configuration example of the SNM detection circuit shown by FIG. 4 in a semiconductor device according to a second embodiment. FIG. 14 is a timing chart showing a schematic operating example of the SNM detection circuit SNMD in FIG. 13. The SNM detection circuit SNMD shown by FIG. 13 further has chattering prevention circuits CPCl, CPCh in addition to the same configuration as that of FIG. 8.

The chattering prevention circuit CPCl has two nMOS transistors MNc1, MNc2. In the two nMOS transistors MNc1, MNc2, a source-drain path is connected in series, and a gate is commonly connected. In addition, in the nMOS transistors MNc1, MNc2, the source-drain path is connected in parallel to the nMOS transistor (first limiting transistor) MNr3 in the replica memory cell RMC.

Here, each of the nMOS transistors MNc1, MNc2 has a gate length (L) larger than that of the nMOS transistor (first pull-down transistor) MNd3. Its gate length (L) may be equal to, for example, that of the nMOS transistor MNr3. The on/off of the nMOS transistors MNc1, MNc2 is controlled by the read assist off signal RAOFF.

Meanwhile, the chattering prevention circuit CPCh has two pMOS transistors MPc1, MPc2. In the two pMOS transistors MPc1, MPc2, a source-drain path is connected in series, and a gate is commonly connected. In addition, in the pMOS transistors MPc1, MPc2, the source-drain path is connected in parallel to the pMOS transistor (second limiting transistor) MPr4 in the replica memory cell RMC.

Here, each of the pMOS transistors MPc1, MPc2 has a gate length (L) larger than that of pMOS transistor (second pull-up transistor) MPu4. Its gate length (L) may be equal to, for example, that of the pMOS transistor MPr4. The on/off of the pMOS transistors MPc1, MPc2 is controlled by an inversion signal of the read assist off signal RAOFF.

FIG. 14 shows one example about a change of the read assist off signal RAOFF depending on temperature Tj. In addition, here, the followings are simultaneously shown: a case of having the chattering prevention circuit CPCh, CPCl, that is, a case of using a configuration shown by FIG. 13 and a case of not having the chattering prevention circuit CPCh, CPCl, that is, a case of using a configuration shown by FIG. 8.

First, in the case of using the configuration shown by FIG. 8, for example, the logic level of the read assist off signal RAOFF can be made unstable in an interval T1 in which the temperature Tj gradually decreases and an interval T2 in which the temperature Tj gradually increases. That is, the temperature Tj does not usually change rapidly. Therefore, the detection result of the SNM can sequentially be changed between the fail state and the path state per clock cycle. As a result, the chattering can occur in the read assist off signal RAOFF.

Meanwhile, in the case of using the configuration shown by FIG. 13, in this example, the clock cycle detecting the pass state instead of the fail state, that is, the clock cycle in which the read assist off signal RAOFF transitions to the “H” level from the “L” level occurs with the decrease of the temperature Tj in the interval T1. Consequently, the chattering prevention circuits CPCl, CPCh are made effective together. As a result, the chattering prevention circuits CPCl, CPCh increase the data retention ability of the replica memory cell only by a predetermined amount.

Specifically, the chattering prevention circuits CPCl, CPCh increase the data retention ability of the memory node MEMt at the “L” level and the data retention ability of the memory node MEMb at the “H” level only by an amount of drive ability of the internal transistor. When the date retention ability is increased like this, the SNM further easily becomes the pass state. Consequently, once transitioning to the “H” level from the “L” level, it becomes difficult for the read assist off signal RAOFF to transition to the “L” level again. As a result, the chattering can be prevented in the interval T1.

A state in which this data retention ability is increased is maintained until the clock cycle detecting the fail state occurs thereafter. In this example, in the interval T2, the clock cycle detecting the fail state instead of the pass state, that is, the clock cycle in which the read assist off signal RAOFF transitions to the “L” level from the “H” level occurs with the increase of the temperature Tj.

When the read assist off signal RAOFF transitions to the “L” level from the “H” level, the chattering prevention circuits CPCl, CPCh are invalidated together. Consequently, the data retention ability of the replica memory cell RMC is decreased to an original state. As a result, the SNM more easily becomes the fail state. Consequently, once transitioning to the “L” level from the “H” level, it becomes difficult for the read assist off signal RAOFF to transition to the “H” level again. As a result, the chattering in the interval T2 can be prevented.

Note that, as shown in FIG. 14, the SNM detection circuit SNMD detects the SNM per clock cycle based on the inputted clock signal CLK, and determines the logic level of the read assist off signal RAOFF according to the detection result. However, the temperature Tj does not rapidly change usually. Consequently, the SNM detection circuit SNMD may be configurated so as to operate in a longer interval of time. That is, the SNM detection circuit SNMD may operate, for example, per two or more clock cycles or may be inputted by dividing the clock signal CLK itself.

### Main Effects by Second Embodiment

As described above, the second embodiment causes the data retention ability of the replica memory cell to have hysteresis characteristics by providing the chattering prevention circuit. Consequently, in addition to the various effects described in the first embodiment, the chattering that can occur in changing the validation/invalidation of the read assist circuit can further be prevented. By preventing the chattering, for example, the surplus operating current with switching the validation/invalidation can be suppressed.

### Third Embodiment

### Details of SNM Detection Circuit

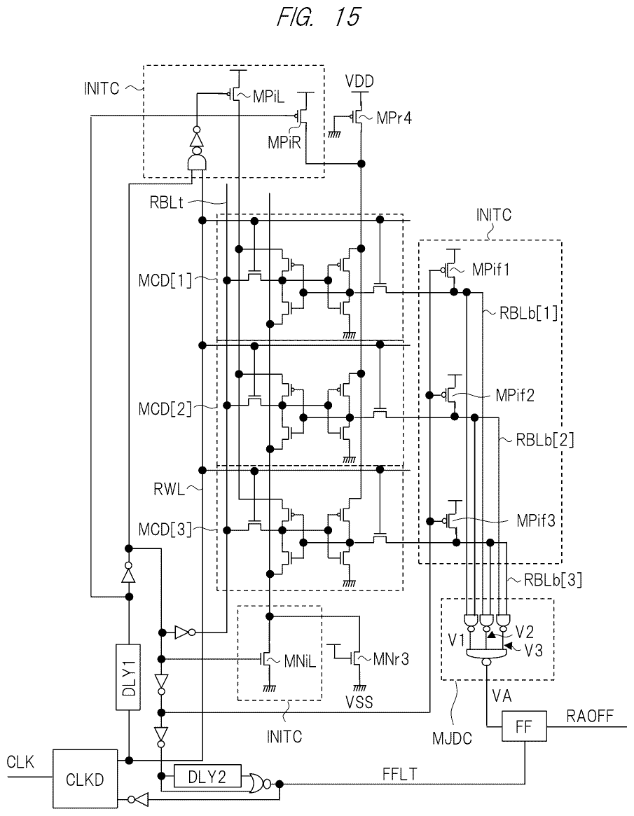

FIG. 15 is a circuit diagram showing a detailed configuration example different from that of FIG. 8 of the

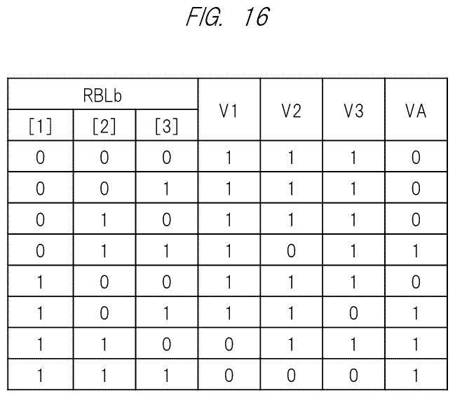

SNM detection circuit SNMD in a semiconductor device according to a third embodiment. FIG. 16 a truth table showing an operating example of a majority determination circuit MJDC of FIG. 15. The SNM detection circuit SNMD shown by FIG. 15 is different from the configuration example shown by FIG. 8 in three points. As a first different point, the plurality of dummy memory cells sharing the replica word line RWL and the normal-rotation-side replica bit line RBLt, specifically, the odd-number dummy memory cells MCD[1] to MCD[3] are provided.

Note that in this example, by using Component [2] shown by FIG. 10B, the nMOS transistor MNr3 and the pMOS transistor MPr4, which are the limiting transistor, are also shared by the plurality of dummy memory cell MCD. Therefore, the dummy memory cell is two or more in number, but, for example, the replica memory cell is substantially provided two or more in number if based on Component [3] shown by FIG. 10C.

As a second different point, the plurality of dummy memory cells MCD[1] to MCD[3], in other words, the plurality of reverse-side replica bit line RBLb[1] to RBLb[3] respectively connected to the plurality of replica memory cells are provided. Along with this, the initialization circuit INITC also has the plurality of pMOS transistors MPif1 to MPif3 respectively connected to the plurality of replica bit lines RBLb[1] to RBLb[3].

As a third different point, the majority determination circuit MJDC connected to the plurality of replica bit lines RBLb[1] to RBLb[3] is provided. The majority determination circuit MJDC inputs the logic level of the plurality of replica bit lines RBLb[1] to RBLb[3], eventually, the plurality of detection results using the plurality of replica memory cells, and calculates majority of the plurality of detection results. Then, the majority determination circuit MJDC outputs a calculation result of the majority to the latch circuit FF.

As shown by FIG. 15, the majority determination circuit MJDC can be configured by, for example, a plurality of NAND gates and the like. As shown in FIG. 16, when many “0” levels (“L” level) among the logic levels of the three replica bit line RBLb[1] to RBLb[3] are included, the majority determination circuit MJDC outputs the “0” level as an output value VA. Meanwhile, when many “1” levels among the logic levels of three replica bit lines RBLb[1] to RBLb[3] are included, the majority determination circuit MJDC outputs the “1” level as the output value VA.

### Main Effects by Third Embodiment

As described above, by using the third embodiment, the affection of the manufacturing variations of the replica memory cell can further be reduced in addition to various effects described in the first embodiment. Specifically, by using Component [1] described in FIG. 10A, the manufacturing variations, for example, variations of detection accuracy of the SNM can be reduced. In addition to this, the circuit area can be increased by applying the majority logic shown by FIGS. 15 and 16, but the affection of the manufacturing variations is averaged by the plurality of replica memory cells, and the variations of the detection accuracy of the SNM can further be reduced.

### Fourth Embodiment

### Application Example of Write Assist

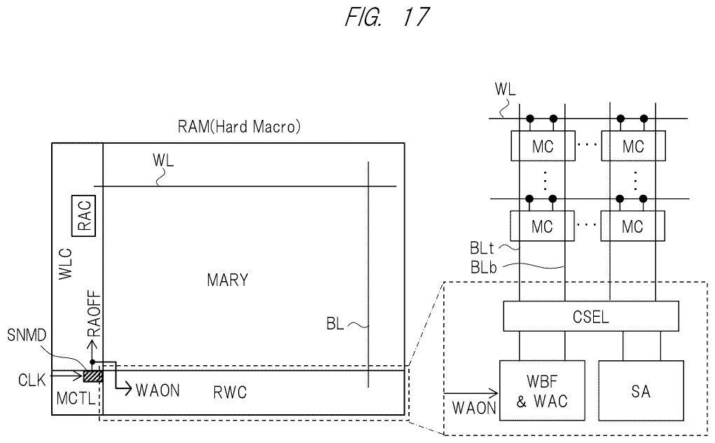

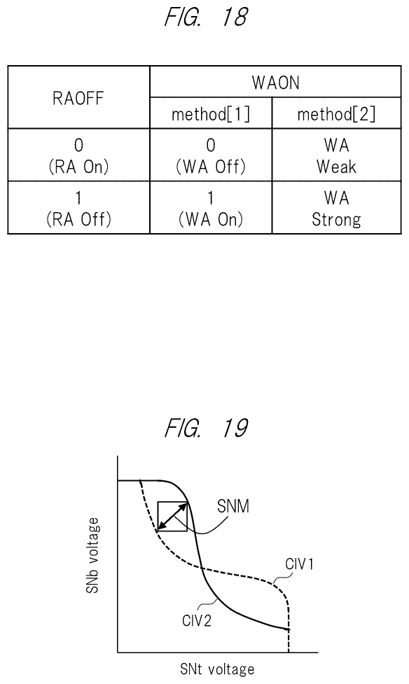

FIG. 17 is a schematic diagram showing an application example of the SNM detection circuit SNMD to a write assist in a semiconductor device according to a fourth embodiment. FIG. 18 is a view showing an operating example of a write assist circuit WAC in FIG. 17. Similarly to cases of FIG. 12 and the like, FIG. 17 shows the volatile memory RAM configurated by the hard macros, specifically, shows the SRAM. The memory control circuit MCTL has the SNM detection circuit SNMD. The word line control circuit WLC has the read assist circuit RAC.

In addition, in this example, the read/write RWC has a column selection circuit CSEL, a sense amplifier circuit SA, a write buffer circuit WBF, and a write assist circuit WAC. The column selection circuit CSEL selects any of the plurality of bit line pairs (BLt, BLb). The sense amplifier circuit SA differentially amplifies a signal of the selected bit line pair (BLt, BLb) at a time of the read access. The write buffer circuit WBF drives the selected bit line pair (BLt, BLb) at a time of the write access.

At the time of the write access, the write buffer circuit WBF drives one of the bit line pair (BLt, BLb) to the “H” level, for example, a level of the power supply voltage VDD and drives the other thereof to the “L” level, for example, a level of the ground voltage VSS. The write assist circuit WAC is configured so that the on/off, that is, the validation/invalidation is switchable based on a write assist signal WAON. When being the validation, the write assist circuit WAC determines, for example, a voltage level by the write buffer circuit WBF so as to become a lower voltage level than that of the ground voltage VSS.

Here, whether the SNM is good or bad and whether the write characteristics are good or bad are usually a contradictory relationship. For example, as shown by FIG. 20, the SNM is in a case of being at the high temperature and in which FS condition is worst. Meanwhile, although a figure is omitted, the write characteristics is in a case of being the low temperature and in which the SF characteristics is worst. Based on such a relationship, the read assist off signal RAOFF can also be used as a write assist on signal WAOC.

That is, as shown by FIG. 18, when the read assist off signal RAOFF is at the “0” level (“L” level), the write assist on signal WAON is also at the “0” level. As a result, the read assist circuit RAC is valid. Meanwhile, the write assist circuit WAC is limited to the validation or a weak assist amount. In addition, when the read assist off signal RAOFF is at the “1” level (“H” level), the write assist on signal WAON is also at the “1” level. As a result, the read assist circuit RAC is invalid. Meanwhile, the write assist circuit WAC is limited to the validation or a strong assist amount.

### Main Effects by Fourth Embodiment

As described above, by using the fourth embodiment, using the common SNM detection circuit makes it possible to properly control the validation/invalidation of the read assist circuit as well as the write assist circuit in addition to various effects described in the first embodiment. Controlling the validation/invalidation of the write assist circuit makes it possible to omit the operation of the unnecessary write assist circuit, for example, to achieve a reduction and the like of the operating current.

As described above, the invention made by the present inventors has specifically been explained based on the embodiments, but the present invention is not limited to the above embodiments and can variously be modified within a range not departing from a gist thereof. For example, the above embodiments have been detailed for easy explanation, and are not limited to an embodiment not always having all the configurations. In addition, a part of a configuration of an embodiment can replaced by a configuration of another embodiment, or a configuration of another embodiment can also be added to a configuration of an embodiment. Furthermore, another configuration may be added to a part of the configuration of each embodiment, and a part of the configuration of each embodiment may be eliminated or replaced with another configuration.

What is claimed is:

1. A semiconductor device comprising:
a SRAM (Static Random Access Memory); and
a detection circuit detecting a static noise margin in the SRAM,
wherein the SRAM has:
a memory array having a word line, a bit line pair, and a memory cell connected to the word line and the bit line pair; and
a read assist circuit switch configurated so as to be capable of switching validation/invalidation, the read assist circuit lowering a word line voltage applied to the word line to secure a static noise margin of the memory cell when being valid, and
wherein the detection circuit has a replica memory cell configurated so as to have date retention ability lower than that of the memory cell, and the detection circuit is configured so as to detect the static noise margin of the memory cell in a pseudo manner by using the replica memory cell and to switch the validation/invalidation of the read assist circuit depending on a detection result.

2. The semiconductor device according to claim 1,
wherein the replica memory cell includes:
a replica word line;
a first replica bit line and a second replica bit line that are the complementary bit line pair;
a first memory node and a second memory node that are the complementary memory node;
a first pull-up transistor and a second pull-up transistor that respectively pull up the first memory node and the second memory node to a high-potential-side power supply voltage;
a first pull-down transistor and a second pull-down transistor that respectively pull down the first memory node and the second memory node to a low-potential-side power supply voltage; and
a first path gate transistor and a second path gate transistor that respectively connect the first memory node and the second memory node to the first replica bit line and the second replica bit line when the replica word line is activated.

3. The semiconductor device according to claim 2,
wherein the replica memory cell further includes:
a first limiting transistor inserted into a current path between the first pull-down transistor and the low-potential-side power supply voltage; and
a second limiting transistor inserted into a current path between the second pull-up transistor and the high-potential-side power supply voltage,
wherein the first limiting transistor has a gate length larger than that of the first pull-down transistor, and
wherein the second limiting transistor has a gate length larger than that of the second pull-up transistor.

4. The semiconductor device according to claim 3,
wherein the replica memory cell is configured by using a transistor having a gate length or a gate width larger than that of the transistor configurating the memory cell.

5. The semiconductor device according to claim 3,
wherein the detection circuit includes:
a sequence control circuit performing an initializing operation and a detecting operation continuous to the initializing operation by using the replica memory cell; and
a latch circuit holding a detection result obtained by using the replica memory cell, and
wherein the sequence control circuit:
in the initializing operation, activates the replica word line and respectively writes an “L” level and a “H” level in the first memory node and the second memory node; and
in the detecting operation, applies the “H” level to the first replicas bit line in a state of activating the replica word line, makes detection about whether the second replica bit line is in a pass state of being capable of maintain the “H” level or in a fail state of being inversed to the “L” level by latching a logic level of the second replica bit line to the latch circuit, invalidates the read assist circuit in a case of the pass state, and validates the read assist circuit in a case of the fail state.

6. The semiconductor device according to claim 5,
wherein the sequence control circuit performs the initializing operation and the detecting operation per clock cycle based on a clock signal inputted.

7. The semiconductor device according to claim 6,
wherein the detection circuit further includes a chattering circuit increasing data retention ability of the replica memory cell only by a predetermined amount in an interval from generation of a clock cycle detecting the pass state instead of the fail state to generation of a clock cycle then detecting the fail state.

8. The semiconductor device according to claim 5,
wherein the detection circuit further includes an initialization circuit used in the initializing operation, and
wherein the initialization circuit has:
a first initial writing transistor connected in parallel to the first limiting transistor, having a gate length smaller than that of the first limiting transistor, becoming an on state at the time of the initializing operation, and becoming an off state at a time of the detecting operation; and
a second initial writing transistor connected in parallel to the second limiting transistor, having a gate length smaller than that of the second limiting transistor, becoming an on state at the time of the initializing operation, and becoming an off state at the time of the detecting operation.

9. The semiconductor device according to claim 8,
wherein the initialization circuit further has a third initial writing transistor inserted into a current path between the first pull-up transistor and the high-potential-side power supply voltage, the third initial writing transistor becoming the state at the time off of the initializing operation and becoming the on state at the time of the detecting operation.

10. The semiconductor device according to claim 2,
wherein the replica memory cell is configured so that relative drive ability between the respective transistors configurating the replica memory cell is different from relative drive ability between the respective transistors configurating the memory cell in order to make the data retention ability lower than that of the memory cell.

11. The semiconductor device according to claim 10,
wherein when a gate width of the first path gate transistor is “W1” and a gate width of the first pull-down transistor is “W2”, a value of a β ratio defined as “W2/W1” becomes smaller than a value of a β ratio of the memory cell.

12. The semiconductor device according to claim 10,
wherein the replica memory cell is configurated so as to increase the drive ability of the first path gate transistor, decrease the drive ability of the first pull-down transistor, and decrease the drive ability of the second pull-up transistor in comparison with the relative drive ability of the memory cell.

13. The semiconductor device according to claim 1,
wherein the SRAM is configurated by a hard macron a having switching terminal for switching the validation/invalidation of the read assist circuit, and
wherein the detection circuit is arranged outside an arrangement region of the hard macron and is connected to the switching terminal.

14. The semiconductor device according to claim 1,
wherein the detection circuit has:
a plurality of replica memory cells comprising the replica memory cell; and
a majority determination circuit calculating majority of a plurality of detection results obtained by using the plurality of replica memory cells.

15. A semiconductor device comprising:
a SRAM (Static Random Access Memory); and
a detection circuit detecting a static noise margin in the SRAM,
wherein the SRAM has:
a memory array having a word line, a bit line pair, a memory cell connected to the word line and the bit line pair;
a read assist circuit configured so as to be capable of switching validation/invalidation, the read assist circuit lowering a word line voltage applied to the word line in order to secure the static noise margin of the memory cell when being valid,
wherein the detection circuit is configured so as to have a replica memory cell, detect the static noise margin of the memory cell in a pseudo manner by using the replica memory cell, and switch the validation/invalidation of the read assist circuit depending on a detection result, and
wherein the replica memory cell is configured so as to have the data retention ability lower than that of the memory cell, and is configured by using a transistor having a gate length or a gate width larger than that of a transistor configurating the memory cell.

16. The semiconductor device according to claim 15,
wherein the replica memory cell has:
a replica word line;
a first replica bit line and a second replica bit line that are the complementary bit line pair;
a first memory node and a second memory node that are the complementary memory node;
a first pull-up transistor and a second pull-up transistor that respectively pull up the first memory node and the second memory node to a high-potential-side power supply voltage;
a first pull-down transistor and a second pull-down transistor that respectively pull down the first memory node and the second memory node to a low-potential-side power supply voltage; and
a first path gate transistor and a second path gate transistor respectively connecting the first memory node and the second memory node to the first replica bit line and the second replica bit line when the replica word line is activated.

17. The semiconductor device according to claim 16,
wherein the replica memory cell further has:
a first limiting transistor r inserted into a current path between the first pull-down transistor and the low-potential-side power supply voltage; and
a second limiting transistor inserted into a current path between the second pull-up transistor and the high-potential-side power supply voltage,
wherein the first limiting transistor has a gate length larger than that of the first pull-down transistor, and
wherein the second limiting transistor has a gate length larger than that of the second pull-up transistor.

18. The semiconductor device according to claim 16,
wherein the replica memory cell is configured so that relative drive ability between the respective transistors configurating the replica memory cell is different from relative drive ability between the respective transistors configurating the memory cell in order to decrease the data retention ability of the memory cell.

19. The semiconductor device according to claim 18,
wherein when a gate width of the first path gate transistor is “W1” and a gate width of the first pull-down transistor is “W2”, a value of β ratio defined as “W2/W1” becomes smaller than a value of β ratio of the memory cell.

20. The semiconductor device according to claim 18,
wherein the replica memory cell is configurated so as to increase the drive ability of the first path gate transistor, decrease the drive ability of the first pull-down transistor, and decrease the drive ability of the second pull-up transistor in comparison with the relative drive ability of the memory cell.
